(19) United States
(12) Patent Application Publication
(10) Pub. No.: US 2023/0307539 A1
(43) Pub. Date: Sep. 28, 2023

(54) LATERAL DIFFUSION FIELD EFFECT TRANSISTOR WITH SILICON-ON-INSULATOR REGION BELOW FIELD PLATE

(71) Applicant: GlobalFoundries U.S. Inc., Malta, NY (US)

(72) Inventor: Jagar Singh, Clifton Park, NY (US)

(73) Assignee: GlobalFoundries U.S. Inc., Malta, NY (US)

(21) Appl. No.: 17/701,751

(22) Filed: Mar. 23, 2022

(51) Int. Cl. H01L 29/78; H01L 29/40; H01L 29/423; H01L 29/66

(52) U.S. Cl. CPC H01L 29/7824; H01L 29/402; H01L 29/42368; H01L 29/66681

(57) ABSTRACT

A structure has a substrate, a drift region within the substrate, a semiconductor-on-insulator structure on the substrate adjacent to the drift region, a gate insulator layer having a first portion on the substrate and a second portion extending over the semiconductor-on-insulator structure, a gate conductor on the first portion, and a field plate on the gate conductor and the second portion.

### BACKGROUND

### Field of the Invention

The present disclosure relates to transistor structures, and more specifically, to lateral diffusion field effect transistor (LDFET) structures.

### Description of Related Art

A lateral diffusion field effect transistor (LDFET) is a field effect transistor that includes a drift region between the gate conductor and the drain region, and the drift region avoids forming a high electric field at the drain junction, which is the p-n junction between the body and the drain region. With LDFETs a large portion of the voltage is consumed within the drift region, which prevents the electric field generated across the gate dielectric from causing breakdown of the gate dielectric.

Field plates can be used with LDFETs to improve control of the field generated by the gate conductor. Field plates are conductive elements, which are placed over the drift region to enhance the performance of a high voltage transistor device by manipulating the electric fields (e.g., reducing peak electric fields) generated by the gate electrode. By manipulating the electric field generated by the gate electrode, the high voltage transistor device can achieve higher breakdown voltages.

### SUMMARY

An exemplary structure herein has a substrate, a drift region within the substrate, a semiconductor-on-insulator structure on the substrate adjacent to the drift region, a gate insulator layer having a first portion on the substrate and a second portion extending over the semiconductor-on-insulator structure, a gate conductor on the first portion, and a field plate on the gate conductor and the second portion.

Another exemplary transistor structure herein has a body region within a substrate. The body region has a first conductivity type. The transistor structure further includes a blocking region within the substrate and a drift region within the substrate. The blocking region is between the body region and the drift region. The transistor structure further includes a source region within the body region. The source region has a second conductivity type. The transistor structure further includes a gate insulator on the blocking region and a gate conductor on the gate insulator. The gate conductor is insulated from the source region. The gate insulator is between the blocking region and the gate conductor. The transistor structure further includes a silicon structure on the drift region. The gate conductor is between the source region and the silicon structure. The transistor structure further includes a drain region within the drift region. The drain region has the second conductivity type. The silicon structure is between the gate conductor and the drain region. The transistor structure further includes a field plate on the gate insulator. A portion of the silicon structure is between the field plate and the drift region. The silicon structure has a buried oxide layer and a silicon layer. The buried oxide layer is between the drift region and the silicon layer.

An additional exemplary transistor structure has a body region within a substrate. The body region has a first conductivity type. The transistor structure further includes a blocking region laterally adjacent (in a lateral direction) the body region within the substrate and a drift region laterally adjacent the blocking region within the substrate. The blocking region is laterally between the body region and the drift region. The transistor structure further includes a source region within the body region. The source region has a second conductivity type. The transistor structure further includes a gate insulator positioned vertically on the blocking region (in a vertical direction perpendicular to the lateral direction) and a gate conductor vertically on the gate insulator. The gate conductor is insulated from the source region. The gate insulator is vertically between the blocking region and the gate conductor. The transistor structure further includes a silicon structure vertically on the drift region. The gate conductor is positioned laterally between the source region and the silicon structure. The transistor structure further includes a drain region within the drift region. The drain region has the second conductivity type. The silicon structure is laterally between the gate conductor and the drain region. The transistor structure further includes a field plate vertically on the gate insulator. A portion of the silicon structure is vertically between the field plate and the drift region. The silicon structure has a buried oxide layer and a silicon layer. The buried oxide layer is vertically between the drift region and the silicon layer.

### BRIEF DESCRIPTION OF THE DRAWINGS

The embodiments herein will be better understood from the following detailed description with reference to the drawings, which are not necessarily drawn to scale and in which:

FIG. 1 is a cross-sectional schematic diagram illustrating a transistor according to embodiments herein;

FIG. 2 is a cross-sectional schematic diagram illustrating a portion of the transistor shown in FIG. 1, according to embodiments herein;

FIGS. 3-6 are cross-sectional schematic diagram illustrating different alternative structures of a portion of the transistor shown in FIG. 1; and

FIGS. 7-11 illustrate different stages of formation of a representative structure according to embodiments herein.

### DETAILED DESCRIPTION

As mentioned above, field plates can be used with LDFETs to improve control of the field generated by the gate conductor. By manipulating the electric field generated by the gate electrode, the high voltage transistor device can achieve higher breakdown voltages. However, the limits on drain voltages are still an item that can be improved. In view of such issues, the structures herein utilize a silicon-on-insulator structure between the drift region and the field plate to support higher drain voltages.

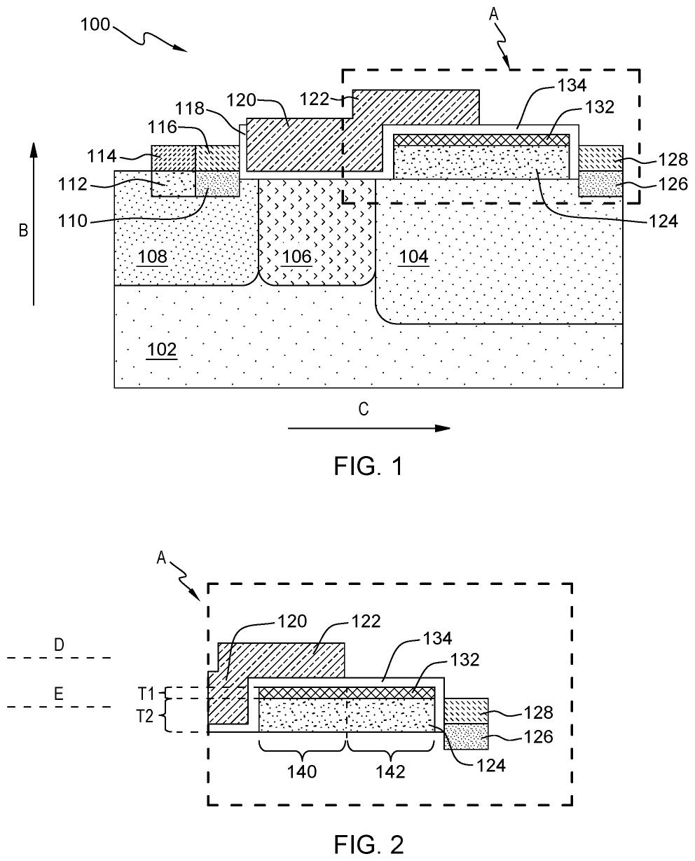

FIG. 1 illustrates one exemplary high-voltage lateral diffusion field effect transistor (LDFET) transistor structure 100 in cross-section that has a body region 108 within a substrate 102. The body region 108 can be, for example, a well region (e.g., dopant implant region) within the substrate 102 (e.g., silicon lightly doped with a P-type dopant). The substrate 102 and body region 108 have a first conductivity type, where the body region 108 has a higher doping concentration than the substrate 102. In one example, the first conductivity type could be a P-type impurity. As is understood by those ordinarily skilled in the art, P-type impurities include items such as boron, aluminum or gallium, etc., and such create deficiencies of valence electrons. Alternatively, the first conductivity type could be an N-type impurity. As is understood by those ordinarily skilled in the art, N-type impurities include items such as antimony, arsenic or phosphorous, etc., and such create excessive valence electrons.

The transistor structure 100 further includes a blocking region 106 laterally adjacent (in a lateral direction C shown in FIG. 1) the body region 108 within the substrate 102. The blocking region 106 is a resistive element between different regions of the substrate and is useful in reducing the coupling of substrate noise between different substrate regions. Sometimes fluoroborylene (boron monofluoride, BF) is used for the body region 108, while the blocking region 106 is an area of the substrate that is blocked/masked during the BF implant resulting in the blocking region 106 sometimes being referred to as a “BFmoat.” Specifically, a masking process is performed during manufacturing to block dopant implantation into the blocking region 106, thereby making the blocking region 106 a high resistance region.

Further, a drift region 104 is laterally adjacent the blocking region 106 within the substrate 102. The drift region 104 has the opposite conductivity type from the body region 108. Thus, if the body region 108 has a P-type dopant, the drift region 104 has an N-type dopant (and vice versa). Positionally, the blocking region 106 is laterally between the body region 108 and the drift region 104.

The transistor structure 100 also includes a source region 110 within the body region 108 and a drain region 126 within the drift region 104. Silicides 116, 128 on the source region (110) and drain region (126) are also shown in FIG. 1. As is understood by those skilled in the art, deposited metal on silicon is subjected to thermal processing to form silicides. The source region 110 and the drain region 126 are conductors and both have the same doping that is opposite the doping of the substrate 102 and body region 108 (e.g., the source/drain have relatively higher second doping concentrations than the drift region 104). In some examples the source region 126 and drain region 128 can be doped crystalline semiconductors. FIG. 1 also shows a body contact region 112 (e.g., a p-tap or an n-tap) that is a conductor and has the first doping type and that laterally directly abuts the source region 110, as well as an associated silicide 114 for the body contact region 112. The body contact region 112 provides for an ohmic connection to the body region 108. The body contact region 112 and the source region 110 are disposed within the body region 108.

A gate insulator 134 contacts the source region 110 and is positioned vertically (e.g., in a vertical direction B that is perpendicular to the lateral direction C) on the blocking region 106. A gate conductor 120 is vertically on the gate insulator 134. An insulator sidewall spacer 118 is positioned laterally between the gate conductor 120 and the source region 110 and its associated silicide 116. The gate conductor 120 is insulated from the source region 110 by the sidewall spacer 118. The gate insulator 134 also can extend vertically between the blocking region 106 and the gate conductor 120 or an individually formed sidewall spacer can be used.

The transistor structure 100 additionally includes a silicon-on-insulator structure 124, 132 (which is sometimes more referred to herein as a “silicon-on-insulator structure,” an “SOT structure,” a “semiconductor-on-insulator structure,” or simply a “silicon structure”) vertically on the drift region 104. The silicon structure 124, 132 has a silicon layer 132 (a semiconductor) vertically on a buried oxide layer 124 (an insulator).

The silicon layer 132 is a semiconductor and can be fully depleted (undoped) partially depleted (partially) doped, etc. As shown in FIG. 1, the gate conductor 120 is positioned laterally between the source region 110 and the silicon structure 124, 132. The silicon structure 124, 132 is laterally between the gate conductor 120 and the drain region 126. A vertical section of the gate insulator 134 (or a similarly positioned sidewall spacer) insulates the silicon structure 124, 132 from the drain region 126 and associated silicide 128. The buried oxide layer 124 is vertically between the drift region 104 and the silicon layer 132.

Also, a conductive field plate 122 (e.g., metal, polysilicon, etc.) is vertically on (e.g., immediately adjacent to, in direct contact with, contacting, etc.) the gate conductor 120 and the gate insulator 134. The field plate 122 enhances the performance of high voltage transistors by manipulating electric fields (e.g., reducing peak electric fields) generated by the gate conductor 120. By manipulating the electric field generated by the gate conductor 120, the high voltage transistor devices can achieve higher breakdown voltages. Further, the silicon structure 124, 132 electrically isolates the drain region 126 which supports higher drain voltages.

FIG. 2 is an expansion of area “A” in FIG. 1. FIG. 2 shows that the silicon structure 124, 132 has two portions: a first silicon structure portion 140 (e.g., half) laterally adjacent the gate conductor 120 and a second silicon structure portion 142 (e.g., half) laterally adjacent the drain region 126. The first silicon structure portion is vertically between the field plate 122 and the drift region 104. The field plate 122 is vertically adjacent only the first silicon structure portion 140 and is not vertically adjacent the second silicon structure portion 142.

As shown in FIG. 2, the gate conductor 120 lies in a first lateral plane (plane D in FIG. 2). FIG. 1 shows that the gate conductor 120 is vertically adjacent the blocking region 106. FIG. 2 shows that the field plate 122 lies in a different second lateral plane (plane E in FIG. 2) and is vertically adjacent the first silicon structure portion 140. The first lateral plane and the second lateral plane extend in the lateral direction C, are non-intersecting, and are parallel to one another. The silicon layer 132 and the buried oxide layer 124 are parallel to each other and to the first lateral plane and the second lateral plane.

In the structure shown in FIG. 2, the field plate 122 extends in the lateral direction C from the gate conductor 120 approximately halfway across the lateral width of the silicon structure 124, 132. Thus, the first silicon structure portion 140 extends laterally approximately one half of the distance from the gate conductor 120 to the drain region 126. This makes the first silicon structure portion 140 and the second silicon structure portion 142 approximately equal in lateral width.

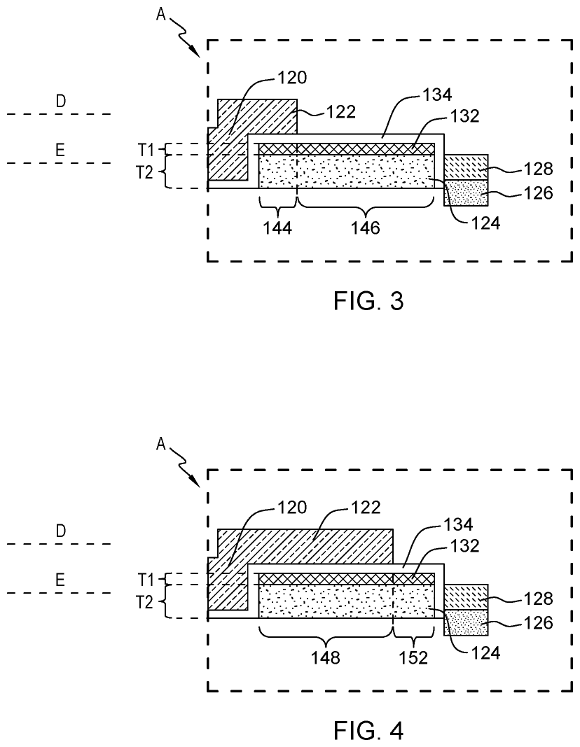

Differently, in the example shown in FIG. 3, a first silicon structure portion 144 (which is merely a different dimension of the first silicon structure portion 140 mentioned above) only extends laterally approximately one quarter of the distance from the gate conductor 120 to the drain region 126. Thus, in the structure shown in FIG. 3, the field plate 122 extends in the lateral direction C from the gate conductor 120 approximately one quarter of the way across the lateral width of the silicon structure 124, 132. This makes the second silicon structure portion 146 approximately three times laterally wider than the first silicon structure portion 144. This structure moves the field plate 122 further from the drain region 126 to even further electrically isolate the drain region 126 and thereby additionally support higher drain voltages.

FIG. 4 illustrates a different structure where a first silicon structure portion 148 (which is merely a different dimension of the first silicon structure portion 140 mentioned above) extends laterally approximately three quarters of the distance from the gate conductor 120 to the drain region 126. Thus, in the structure shown in FIG. 4, the field plate 122 extends in the lateral direction C from the gate conductor 120 approximately three quarters of the way across the lateral width of the silicon structure 124, 132. This makes the first silicon structure portion 148 approximately three times laterally wider than the second silicon structure portion 150. This structure moves the field plate 122 closer to the drain region 126 to allow the field plate 122 to provide more manipulation of the electric field generated by the gate conductor 120.

While FIGS. 2-4 illustrate examples where the first silicon structure portion 148 extends laterally approximately (e.g., within 5%, 10%, 20%, etc., in terms of distance) one quarter, one-half, and three quarters of the distance from the gate conductor 120 to the drain region 126. However, the claims below are not limited to only these three cases and instead, such are merely a few limited examples of the general case for which the conductive field plate 122 extends in the lateral direction C from the gate conductor 120 and partially across the lateral width of the silicon structure 124, 132 toward the drain region 126.

In the example shown in FIG. 2, the buried oxide layer 124 (an insulator) is thicker (thickness T2), in the vertical direction B, than the silicon layer 132 (thickness T1). In one example, the buried oxide layer 124 is at least twice as thick as the silicon layer 132 in the vertical direction B. Having a relatively thicker buried oxide layer 124 provides additional insulation to the drain region 126 to additionally electrically isolate the drain region 126 and thereby additionally support higher drain voltages.

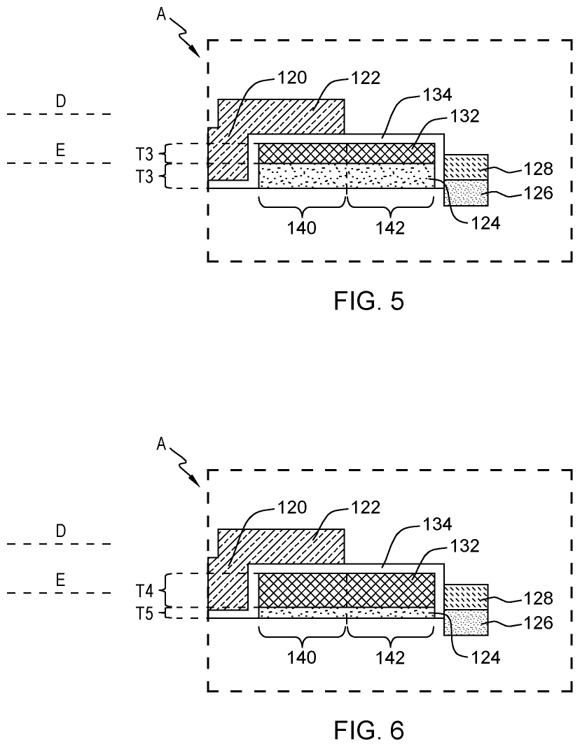

Differently, in the structure shown in FIG. 5, the buried oxide layer 124 (an insulator) has the same thickness (thickness T3) in the vertical direction B as the silicon layer 132. Thus, in the example shown in FIG. 5, the semiconducting effect of the silicon layer 132 allows the field plate 122 to provide more manipulation of the electric field generated by the gate conductor 120, while still providing some electrical isolation to the drain region 126 to additionally support higher drain voltages.

FIG. 6 illustrates yet another structure where the silicon layer 132 is thicker (thickness T4), in the vertical direction B, than the buried oxide layer 124 (thickness T5). In one example, the silicon layer 132 is at least twice as thick as the buried oxide layer 124 (an insulator) in the vertical direction B. Thus, with the structure shown in FIG. 6, the semiconducting effect of the silicon layer 132 allows the field plate 122 to provide even more manipulation of the electric field generated by the gate conductor 120, while still providing some electrical isolation to the drain region 126 to still support higher drain voltages.

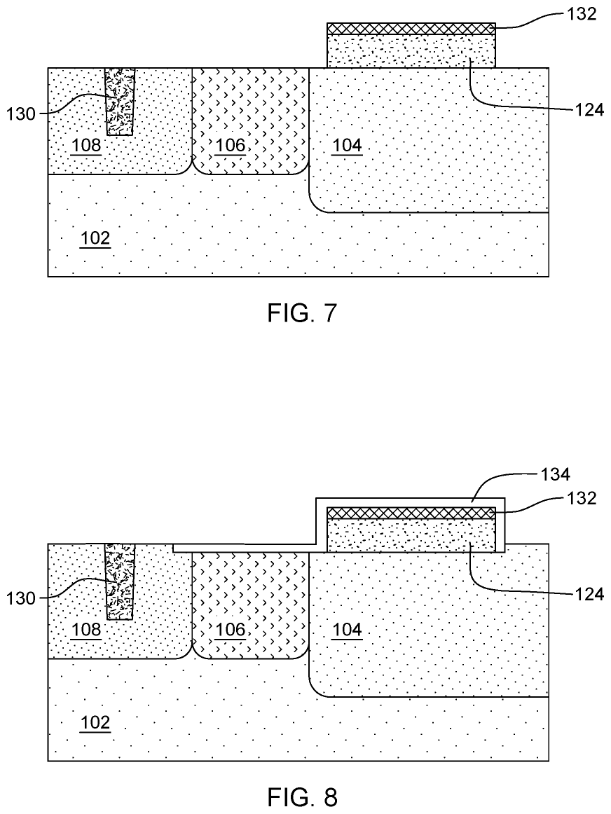

FIGS. 7-11 illustrate different stages of formation of another representative structure similar to that shown in FIG. 1. Specifically, in FIG. 7 the substrate 102 is provided and the drift region 104, blocking region 106, and body region 108 are formed through various well-known masking and implantation processes. While the structure shown in FIG. 1 positions the body contact 112 (and associated silicide 114) in contact with the source 110 (and associated silicide 116), in the structure shown in FIGS. 7-11 the body contact 112 (and associated silicide 114) is insulated from the source 110 (and associated silicide 116) by a shallow trench isolation structure (STI) 130 and insulator 115. FIG. 7 shows formation of the STI 130 using recessing and insulator deposition/growth techniques.

Further, the buried oxide layer 124 and silicon layer 132 are formed/patterned on the substrate 102. FIG. 8 illustrates that the gate oxide 134 is grown/deposited and patterned. This allows the gate oxide 134 to be positioned on the sidewalls of the silicon structure 124, 132. The gate oxide 134 can be one or more layers suitable for use as a gate dielectric.

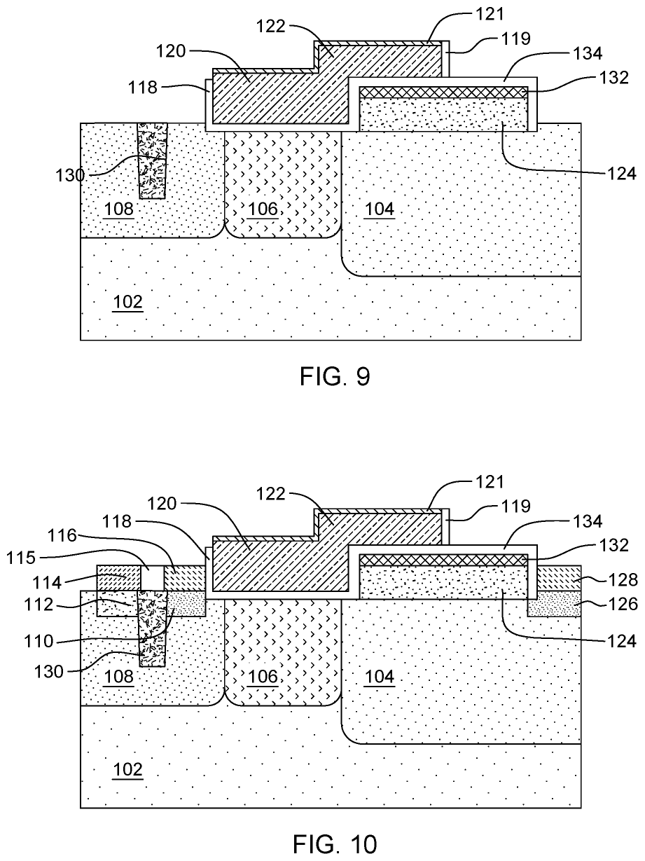

FIG. 9 shows the structure after formation/patterning of the gate conductor 134 and field plate 122 (and associated dielectric cap 121) and formation of sidewall spacers 118, 119 on such structures. The gate conductor 120 and field plate 122 can be formed in separate steps (potentially of different conductors) or the gate conductor 120 and field plate 122 can be formed in a single process and can be formed of the same conductor material. Additionally, a multi-step patterning process could be used so that the gate dielectric layer 134 still covers the entire SOI structure 124, 132. In some options, a silicide blocking (SAB) layer can be formed on the SOI structure 124, 132 to prevent silicide formation thereon or a silicide layer could be formed on the SOI structure 124, 132.

FIG. 10 illustrates the structure after the source region 110, the body contact region 112 (and their associated silicides 114, 116), and the drain region 126 (and its associated silicide 128) are formed through masking, implantation, and silicide formation processes. Specifically, in one example, this processing can form a first mask covering a designated area for a P+ body contact region and form N+ source and drain regions (e.g., by dopant implantation process or, alternatively by etching source and drain trenches and filling with N+ epitaxially grown material or optionally overfilling for raised source and drain, not shown). This processing can remove the first mask and form a second mask exposing designated area for the P+ body contact region. Such processing can continue by forming a P+ body contact region (e.g., by dopant implantation process or, alternatively, by etching body contact trench and filling with P+ epitaxially grown material or optionally overfill for raised body contact, not shown). Optionally, this processing can deposit and pattern a silicide blocking (SAB) layer to protect the silicon structure 124, 132 during subsequent silicide formation processes. Any such SAB layer should be a different dielectric material than gate cap 121.

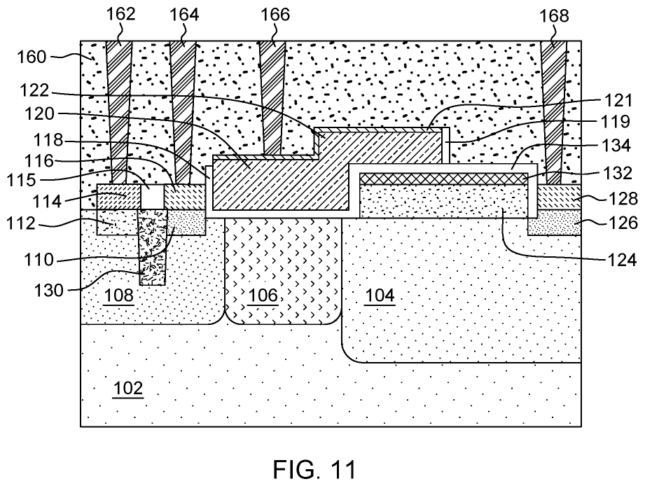

FIG. 11 illustrates middle-of-the-line (MOL) processing that includes formation of an inter-layer dielelectric 160 and formation of a body contact 162, source contact 164, gate/plate contact 166, and a drain contact 168 through the interlayer dielectric 160.

The foregoing structures can be used within a PCell (parameterized cell). PCells have a set of parameters that define the actual implementation of the cell. For example, two instances of a particular PCell could be placed, such that each instance has difference parameters. Each instance would have the same basic function, but they would have different performance and difference sizes.

For purposes herein, a “semiconductor” material has an electrical conductivity value falling between that of a conductor, such as metallic copper, and an insulator, such as glass. A dopant or an impurity is a trace element deliberately added to a semiconductor. Some examples of semiconductors are silicon, germanium, gallium arsenide, and elements near the so-called “metalloid staircase” on the periodic table. As used herein, “implantation processes” can take any appropriate form (whether now known or developed in the future) and can be, for example, ion implantation, etc. Epitaxial growth occurs in a heated (and sometimes pressurized) environment that is rich with a gas of the material that is to be grown.

For purposes herein, an “insulator” is a relative term that means a material or structure that allows substantially less (<95%) electrical current to flow than does a “conductor.” The dielectrics (insulators) mentioned herein can, for example, be deposited (e.g., deposited silicon dioxide) and/or grown from either a dry oxygen ambient or steam and then patterned. Alternatively, the dielectrics herein may be formed (grown or deposited) from any of the many candidate low dielectric constant materials (low-K (where K corresponds to the dielectric constant of silicon dioxide) materials such as fluorine or carbon-doped silicon dioxide, porous silicon dioxide, porous carbon-doped silicon dioxide, spin-on silicon or organic polymeric dielectrics, etc.) or high dielectric constant (high-K) materials, including but not limited to silicon nitride, silicon oxynitride, a gate dielectric stack of SiO₂ and Si₃N₄, hafnium oxide (HfO₂), hafnium zirconium oxide (HfZrO₂), zirconium dioxide (ZrO₂), hafnium silicon oxynitride (HfSiON), hafnium aluminum oxide compounds (HfAlOₓ), other metal oxides like tantalum oxide, etc. The thickness of dielectrics herein may vary contingent upon the required device performance.

The conductors mentioned herein can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as tungsten, hafnium, tantalum, molybdenum, titanium, or nickel, or a metal silicide, any alloys of such metals, and may be deposited using physical vapor deposition, chemical vapor deposition, or any other technique known in the art.

There are various types of transistors, which have slight differences in how they are used in a circuit. For example, a bipolar transistor has terminals labeled base, collector, and emitter. A small current at the base terminal (that is, flowing between the base and the emitter) can control, or switch, a much larger current between the collector and emitter terminals. Another example is a field-effect transistor, which has terminals labeled gate, source, and drain. A voltage at the gate can control a current between source and drain. Within such transistors, a semiconductor (channel region) is positioned between the conductive source region and the similarly conductive drain (or conductive source/emitter regions), and when the semiconductor is in a conductive state, the semiconductor allows electrical current to flow between the source and drain, or collector and emitter. The gate is a conductive element that is electrically separated from the semiconductor by a “gate oxide” (which is an insulator); and current/voltage within the gate changes makes the channel region conductive, allowing electrical current to flow between the source and drain. Similarly, current flowing between the base and the emitter makes the semiconductor conductive, allowing current to flow between the collector and emitter.

A positive-type transistor “P-type transistor” uses impurities such as boron, aluminum or gallium, etc., within an intrinsic semiconductor substrate (to create deficiencies of valence electrons) as a semiconductor region. Similarly, an “N-type transistor” is a negative-type transistor that uses impurities such as antimony, arsenic or phosphorous, etc., within an intrinsic semiconductor substrate (to create excessive valence electrons) as a semiconductor region.

Generally, transistor structures, in one example, can be formed by depositing or implanting impurities into a substrate to form at least one semiconductor channel region, bordered by shallow trench isolation regions below the top (upper) surface of the substrate. A “substrate” herein can be any material appropriate for the given purpose (whether now known or developed in the future) and can be, for example, silicon-based wafers (bulk materials), ceramic materials, organic materials, oxide materials, nitride materials, etc., whether doped or undoped. The “shallow trench isolation” (STI) structures are generally formed by patterning openings/trenches within the substrate and growing or filling the openings with a highly insulating material (this allows different active areas of the substrate to be electrically isolated from one another).

While only one or a limited number of transistors are illustrated in the drawings, those ordinarily skilled in the art would understand that many different types transistor could be simultaneously formed with the embodiment herein and the drawings are intended to show simultaneous formation of multiple different types of transistors; however, the drawings have been simplified to only show a limited number of transistors for clarity and to allow the reader to more easily recognize the different features illustrated. This is not intended to limit this disclosure because, as would be understood by those ordinarily skilled in the art, this disclosure is applicable to structures that include many of each type of transistor shown in the drawings.

The terminology used herein is for the purpose of describing particular embodiments only and is not intended to be limiting of the foregoing. As used herein, the singular forms “a,” “an,” and “the” are intended to include the plural forms as well, unless the context clearly indicates otherwise. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element.

Embodiments herein may be used in a variety of electronic applications, including but not limited to advanced sensors, memory/data storage, semiconductors, microprocessors and other applications. A resulting device and structure, such as an integrated circuit (IC) chip can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The description of the present embodiments has been presented for purposes of illustration and description but is not intended to be exhaustive or limited to the embodiments in the form disclosed. Many modifications and variations will be apparent to those of ordinary skill in the art without departing from the scope and spirit of the embodiments herein. The embodiments were chosen and described in order to best explain the principles of such, and the practical application, and to enable others of ordinary skill in the art to understand the various embodiments with various modifications as are suited to the particular use contemplated.

While the foregoing has been described in detail in connection with only a limited number of embodiments, it should be readily understood that the embodiments herein are not limited to such disclosure. Rather, the elements herein can be modified to incorporate any number of variations, alterations, substitutions or equivalent arrangements not heretofore described, but which are commensurate with the spirit and scope herein. Additionally, while various embodiments have been described, it is to be understood that aspects herein may be included by only some of the described embodiments. Accordingly, the claims below are not to be seen as limited by the foregoing description. A reference to an element in the singular is not intended to mean “one and only one” unless specifically stated, but rather “one or more.” All structural and functional equivalents to the elements of the various embodiments described throughout this disclosure that are known or later, come to be known, to those of ordinary skill in the art are expressly incorporated herein by reference and intended to be encompassed by this disclosure. It is therefore to be understood that changes may be made in the particular embodiments disclosed which are within the scope of the foregoing as outlined by the appended claims.

What is claimed is:

1. A structure comprising:
a substrate;
a drift region within the substrate;
a semiconductor-on-insulator structure on the substrate adjacent to the drift region;
a gate insulator layer having a first portion on the substrate and a second portion extending over the semiconductor-on-insulator structure;
a gate conductor on the first portion; and
a field plate on the gate conductor and the second portion.

2. The structure according to claim 1, wherein the semiconductor-on-insulator comprises:
a first semiconductor-on-insulator portion adjacent the gate conductor; and
a second semiconductor-on-insulator portion adjacent a drain region,
wherein the field plate is adjacent only the first semiconductor-on-insulator portion and is not adjacent the second semiconductor-on-insulator portion.

3. The structure according to claim 2, wherein the first semiconductor-on-insulator portion extends at least one quarter of a distance from the gate conductor to the drain region.

4. The structure according to claim 2, wherein the gate conductor lies in a first plane and is adjacent a blocking region, wherein the field plate lies in a second plane and is adjacent the first semiconductor-on-insulator portion, and wherein the first plane and the second plane are non-intersecting and parallel to one another.

5. The structure according to claim 4, wherein the semiconductor-on-insulator structure comprises a buried oxide layer and a silicon layer, wherein the silicon layer and the buried oxide layer are parallel to each other and to the first plane and the second plane, wherein the buried oxide layer is thicker, in a first direction, than the silicon layer, and wherein the first direction is perpendicular to the first plane and the second plane.

6. The structure according to claim 5, wherein the buried oxide layer is at least twice as thick as the silicon layer in the first direction.

7. The structure according to claim 1, further comprising a gate insulator between the gate conductor and the semiconductor-on-insulator structure.

8. A transistor structure comprising:
a body region within a substrate, wherein the body region has a first conductivity type;
a blocking region within the substrate;
a drift region within the substrate, wherein the blocking region is between the body region and the drift region;
a source region within the body region, wherein the source region has a second conductivity type;
a gate insulator on the blocking region;
a gate conductor on the gate insulator, wherein the gate insulator is between the blocking region and the gate conductor;
a silicon structure on the drift region, wherein the gate conductor is between the source region and the silicon structure;
a drain region within the drift region, wherein the drain region has the second conductivity type, and wherein the silicon structure is between the gate conductor and the drain region; and
a field plate on the gate insulator, wherein a portion of the silicon structure is between the field plate and the drift region,
wherein the silicon structure comprises a buried oxide layer and a silicon layer, and
wherein the buried oxide layer is between the drift region and the silicon layer.

9. The transistor structure according to claim 8, wherein the silicon structure comprises:
a first silicon structure portion adjacent the gate conductor; and
a second silicon structure portion adjacent the drain region,
wherein the field plate is adjacent only the first silicon structure portion and is not adjacent the second silicon structure portion.

10. The transistor structure according to claim 9, wherein the first silicon structure portion extends at least one quarter of a distance from the gate conductor to the drain region.

11. The transistor structure according to claim 9, wherein the gate conductor lies in a first plane and is adjacent the blocking region, wherein the field plate lies in a second plane and is adjacent the first silicon structure portion, and wherein the first plane and the second plane are non-intersecting and parallel to one another.

12. The transistor structure according to claim 11, wherein the silicon layer and the buried oxide layer are parallel to each other and to the first plane and the second plane, wherein the buried oxide layer is thicker, in a first direction, than the silicon layer, and wherein the first direction is perpendicular to the first plane and the second plane.

13. The transistor structure according to claim 12, wherein the buried oxide layer is at least twice as thick as the silicon layer in the first direction.

14. The transistor structure according to claim 8, wherein the gate insulator is between the gate conductor and the silicon structure.

15. A transistor structure comprising:
a body region within a substrate, wherein the body region has a first conductivity type;
a blocking region laterally adjacent, in a lateral direction, the body region within the substrate;
a drift region laterally adjacent the blocking region within the substrate, wherein the blocking region is laterally between the body region and the drift region;
a source region within the body region, wherein the source region has a second conductivity type;
a gate insulator positioned vertically on the blocking region, in a vertical direction perpendicular to the lateral direction;
a gate conductor vertically on the gate insulator, wherein the gate conductor is insulated from the source region, and wherein the gate insulator is vertically between the blocking region and the gate conductor;
a silicon structure vertically on the drift region, wherein the gate conductor is positioned laterally between the source region and the silicon structure;
a drain region within the drift region, wherein the drain region has the second conductivity type, and wherein the silicon structure is laterally between the gate conductor and the drain region; and
a field plate vertically on the gate insulator, wherein a portion of the silicon structure is vertically between the field plate and the drift region,
wherein the silicon structure comprises a buried oxide layer and a silicon layer, and
wherein the buried oxide layer is vertically between the drift region and the silicon layer.

16. The transistor structure according to claim 15, wherein the silicon structure comprises:
a first silicon structure half laterally adjacent the gate conductor; and
a second silicon structure half laterally adjacent the drain region,
wherein the field plate is vertically adjacent only the first silicon structure half and is not vertically adjacent the second silicon structure half.

17. The transistor structure according to claim 16, wherein the first silicon structure half extends laterally at least one quarter of a distance from the gate conductor to the drain region.

18. The transistor structure according to claim 16, wherein the gate conductor lies in a first lateral plane and is vertically adjacent the blocking region, wherein the field plate lies in a second lateral plane and is vertically adjacent the first silicon structure half, and wherein the first lateral plane and the second lateral plane extend in the lateral direction, are non-intersecting, and are parallel to one another.

19. The transistor structure according to claim 18, wherein the silicon layer and the buried oxide layer are parallel to each other and to the first lateral plane and the second lateral plane, wherein the buried oxide layer is thicker, in the vertical direction, than the silicon layer.

20. The transistor structure according to claim 15, wherein the buried oxide layer is at least twice as thick as the silicon layer in the vertical direction.
